(19) United States
(12) Patent Application Publication
(10) Pub. No.: US 2026/0165180 A1
(43) Pub. Date: Jun. 11, 2026

(54) PACKAGE METHOD FOR PARALLELING POWER SEMICONDUCTOR DEVICES

(71) Applicant: SEMICONDUCTOR COMPONENTS INDUSTRIES, LLC, Scottsdale, AZ (US)

(72) Inventors: Yi-Feng HSIA, Chandler, AZ (US); Romel N. MANATAD, Liloan (PH)

(73) Assignee: SEMICONDUCTOR COMPONENTS INDUSTRIES, LLC, Scottsdale, AZ (US)

(21) Appl. No.: 19/405,815

(22) Filed: Dec. 2, 2025

Related U.S. Application Data
(60) Provisional application No. 63/730,575, filed on Dec. 11, 2024.

(51) Int. Cl. H10W 72/60; H10W 70/40; H10W 72/00; H10W 90/00; H10W 90/26

(52) U.S. Cl. CPC H10W 72/637; H10W 70/481; H10W 72/871; H10W 90/26; H10W 90/756; H10W 90/762; H10W 90/766

(57) ABSTRACT

Specific implementations of semiconductor packages may include: a plurality of leads, a first clip coupled to a first lead of a plurality of leads, a second clip coupled to a second lead of the plurality of leads, a first die coupled between a source pad and the first clip, and a second die coupled between the first clip and the second clip. The first die may include a gate, a drain, and a source that are connected in parallel with a gate, a drain, and a source of the second die. The first clip may be coupled to the drain of the first die and to the drain of the second die. A wirebond may electrically connect the gate of the second die to a third lead of the plurality of leads to which the gate of the first die is also electrically connected.

### CROSS REFERENCE TO RELATED APPLICATIONS

This document claims the benefit of the filing date of U.S. Provisional Patent Application 63730575, entitled “Power Semiconductor Package” to Hsia et al. which was filed on Dec. 11, 2024, the disclosure of which is hereby incorporated entirely herein by reference.

### BACKGROUND

### 1. Technical Field

Aspects of this document relate generally to semiconductor packages, such as wafer scale or chip scale packages. More specific implementations involve semiconductor packages including paralleling die structures. Particular implementations also include semiconductor packages that include semiconductor die that include silicon carbide thereon.

### 2. Background

Semiconductor packages work to facilitate electrical and physical connections to an electrical die or electrical component in the package. Various designs have been devised that work to protect a semiconductor die from shock or vibration. Some package designs also assist with protecting a semiconductor die from electrostatic discharge.

### SUMMARY

Implementations of semiconductor packages may include: a plurality of leads, a first clip coupled to a first lead of a plurality of leads, a second clip coupled to a second lead of the plurality of leads, a first die coupled between a source pad and the first clip, and a second die coupled between the first clip and the second clip. The first die may include a gate, a drain, and a source that are connected in parallel with a gate, a drain, and a source of the second die. The first clip may be coupled to the drain of the first die and to the drain of the second die. A wirebond may electrically connect the gate of the second die to a third lead of the plurality of leads to which the gate of the first die is also electrically connected.

Implementations of semiconductor packages may include one, all, or any of the following:

The package may be a single side cooled package.

The package may be a dual side cooled package.

The gate of the first die and the gate of the second die may be commonly controlled using a third lead.

The first lead of the plurality of leads may be a common drain lead.

The second clip may be configured to expose a gate pad of the second die.

The first die and the second die may be surrounded by a mold compound.

Implementations of semiconductor packages may include: a first lead, a second lead, a third lead, and a source pad; a first clip coupled to the first lead; a first die coupled between the source pad and the first clip; and a second die coupled between the first clip and the second clip. The first die may have a gate, a drain, and a source that are connected in parallel with a gate, a drain, and a source of the second die. The first clip may be coupled to the drain of the first die and to the drain of the second die. The gate of the first die and the gate of the second die may be coupled to the third lead. The second clip may further include a cutout that exposes a pad of the gate of the second die.

Implementations of semiconductor packages may include one, all, or any of the following:

The package may be a single side cooled package.

The package may be a dual side cooled package.

The third lead may be used to commonly control the gate of the first die and the gate of the second die.

The first lead may be a common drain lead.

The cutout of the second clip may be configured to permit wirebonding to the pad of the gate of the second die.

Implementations of semiconductor packages may include: a first drain lead coupled to a first clip; a second source lead coupled to a second clip; a first die having a drain coupled between a source pad and the first clip, the drain of the first die coupled to the first clip; and a second die having a drain coupled between the first clip and the second clip, the drain of the second die coupled to the first clip. The first die may have a first gate and the second die may have a second gate. The first gate the second gate may be electrically connected through a wirebond. The package may be configured to decrease electromagnetic interference (EMI) in an inductor when coupled with the inductor.

Implementations of semiconductor packages may include one, all, or any of the following:

The electromagnetic interference (EMI) may be an antenna effect.

The package may be a single side cooled package.

The package may be a dual side cooled package.

The package may further include a common gate lead electrically connected with the first gate and the second gate.

The first drain lead may be a common drain lead.

The second clip may be coupled to a common source lead.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is an electrical schematic of an implementations of a common gate semiconductor device;

FIG. 2 is a side, cross-sectional view of an implementation of a single side cooled semiconductor package;

FIG. 3 is a side, cross-sectional view of an implementations of a dual side cooled semiconductor package;

FIG. 4 is a top, perspective view of an implementation of a parallel source semiconductor package with a cutout in the corner of a second clip;

FIG. 5 is a side, cross-sectional view of the semiconductor package implementation of FIG. 4;

FIG. 6 is a top perspective view of an implementation of a single side cooled implementation of the package of FIG. 4;

FIG. 7 is a top perspective view of a dual side cooled implementation of the semiconductor package of FIG. 4;

FIG. 8 is a bottom perspective view of the semiconductor package implementation of FIG. 4 including a mold compound;

FIG. 9 is a top perspective view of an implementation of a parallel source die package with a cutout in the side of a second clip;

FIG. 10 is a side, cross-sectional view of the semiconductor package implementation of FIG. 9;

FIG. 11 is a top perspective view of a single side cooled implementation of the semiconductor package of FIG. 9 with mold compound thereon;

FIG. 12 is a top perspective view of a dual side cooled implementation of the semiconductor package of FIG. 9;

FIG. 13 is a bottom perspective view of the semiconductor package implementation of FIG. 9 including the mold compound;

FIG. 14 is a bottom perspective partial see-through view of an implementation of a semiconductor package with a common gate lead/pad;

FIGS. 15-22 illustrate a semiconductor package after various processing steps during assembly a package implementation like that illustrated in FIG. 7;

FIG. 23 is an electrical schematic of an implementation of a synchronous buck circuit that includes single die semiconductor device packages;

FIG. 24 is a side cross-sectional view of an implementation of a single semiconductor die device package;

FIG. 25 is an electrical schematic of an electrical circuit that includes a source terminal for center tap inductors/transformers that includes an implementation of a two-die device package like those disclosed herein wherein the die are connected in parallel;

FIG. 26 is an electrical schematic of a semiconductor device package with two die that has the gate of each die connected to a separate lead;

FIG. 27 is a bottom perspective view of an implementation of a two die semiconductor device package with two gate leads;

FIG. 28 is a top perspective view of an implementation of a two die device package with two gate leads; and

FIG. 29 is a graph illustrating an efficiency curve demonstrating the effect of different forms of gate control.

### DESCRIPTION

This disclosure, its aspects and implementations, are not limited to the specific components, assembly procedures or method elements disclosed herein. Many additional components, assembly procedures and/or method elements known in the art consistent with the intended semiconductor device packages will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such semiconductor device packages, and implementing components and methods, consistent with the intended operation and methods.

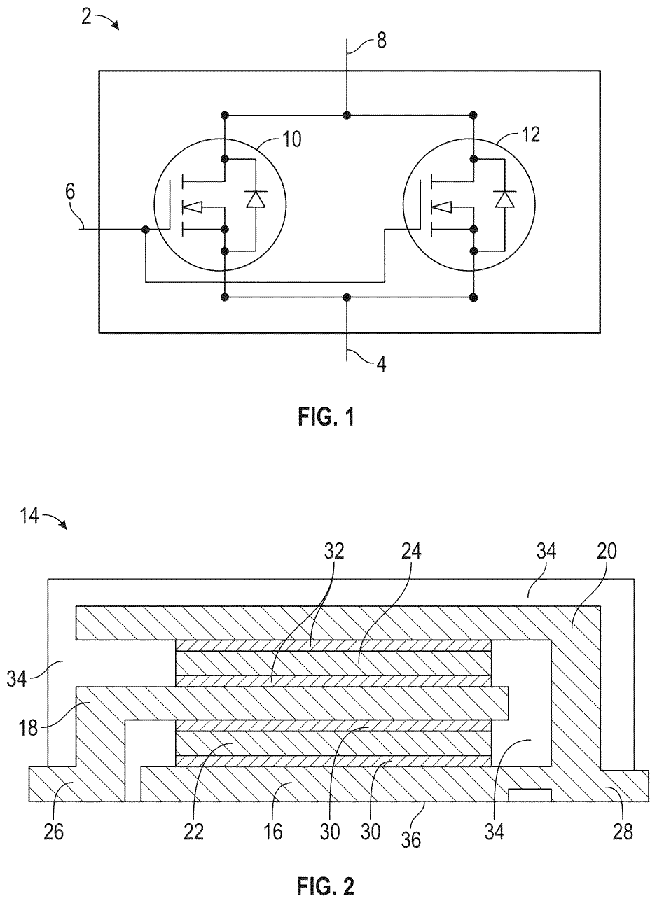

Referring to FIG. 1, an electrical schematic 2 of a single/common/parallel gate electrical semiconductor device is illustrated. The schematic 2 illustrated in FIG. 1 is for a semiconductor package device that includes a single source pad 4, a single gate pad 6, and a single drain pad 8. The package includes a first MOSFET semiconductor die 10 and a second MOSFET semiconductor die 12. The first die 10 is oriented in a source down configuration and the second die 12 is oriented in a drain down configuration. The first die 10 includes a gate, a drain, and a source. The second die 12 includes a gate, a drain, and a source. The gate of the first die 10 is wired in parallel with the gate of the second die 12 to the single gate pad 6. The drain of the first die 10 is wired in parallel with the drain of the second die 12 to the single drain pad 8. The source of the first die 10 is wired in parallel with the source of the second die 12 to the single source pad 4.

Referring to FIG. 2, a side, cross-sectional view of an implementation of a single side cooled semiconductor package 14 is illustrated. In this implementation, the semiconductor package is a no-lead package where the leads do not extend from the package envelope except a small distance due mainly to coatings covering the leads. The package 14 illustrated in FIG. 2 includes a source pad 16 and a plurality of source leads on the bottom edges of the package 14. While a plurality of leads is described in this implementation and in the examples herein, a single lead may be employed for source, drain, and gate connections in other package designs. As illustrated, the package 14 further includes a first clip 18, a second clip 20, a first die 22, and a second die 24. The first clip 18 is coupled to a first lead 26 of the plurality of leads and the second clip 20 is coupled to a second lead 28 of the plurality of leads. The first lead 26 of the plurality of leads in this implementation is a common drain lead. The second lead 28 is a common source lead. The first die 22 is coupled between the source pad 16 and the first clip 18 via a die bonding or die attach material 30 that is electrically and thermally conductive. The die bonding material 30 is on the top side (drain side) of the first die 22 and on the bottom side (source side) of the first die 22. The second die 24 is coupled between the first clip 18 and the second clip 20 via die bonding or attach material 32 that is electrically and thermally conductive. The die bonding material 32 is on the top side (source side) of the second die 24 and on the bottom side (drain side) of the second die 24. The first die 22 of the package includes a gate, a drain, and a source. The second die 24 of the package includes a gate, a drain, and a source. While not shown in FIG. 2, the gate of the first die 22 and the gate of the second die 24 are connected together, or in parallel. The drain of the first die 22 and drain of the second die 24 are connected together or in parallel with the first clip 18 to the first lead 26. The source of the first die 22 and source of the second die 24 are connected together or in parallel with the second clip 20 and to the second lead 28 w As illustrated, the first die 22 and the second die 24 are surrounded by mold compound 34. The package 2 is encased in mold compound 34 on all sides leaving the source pad 16, first lead 26, and second lead 28 exposed on the bottom side 36 of the package 2. As a result, the package 2 of FIG. 2 a single side cooled package where removal of heat from the package takes place primarily through the source pad 16.

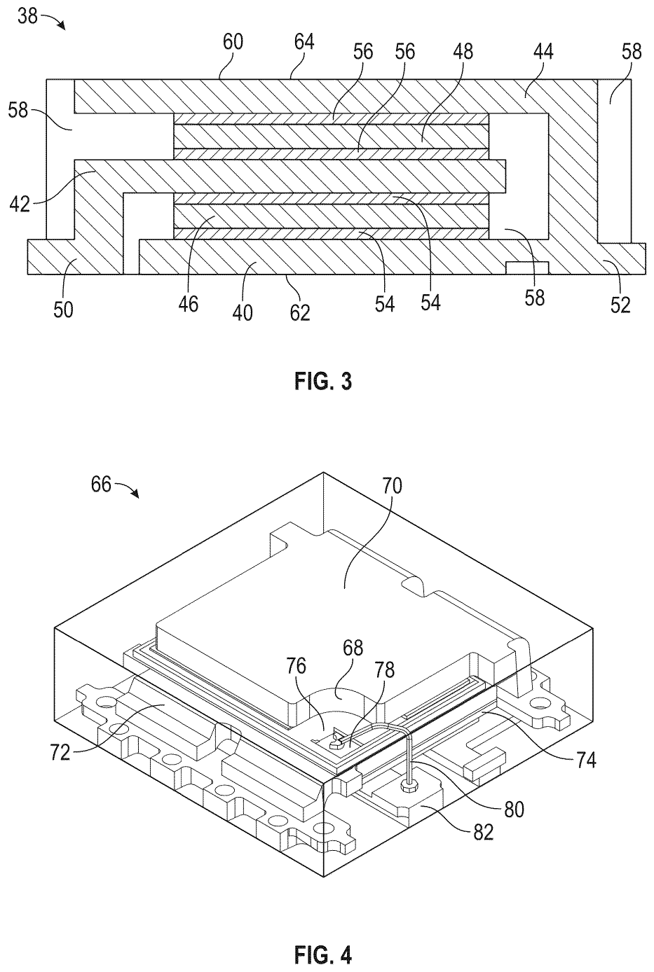

Referring to FIG. 3, a side, cross-sectional view of an implementation of a dual side cooled semiconductor package 38 is illustrated. The package 38 of FIG. 3 includes a source pad 40 and a plurality of leads on the bottom side of the package 38. The package 38 further includes a first clip 42, a second clip 44, a first die 46, and a second die 48. The first clip 42 is coupled to a first lead 50 of the plurality of leads and the second clip 44 is coupled to a second lead 52 of the plurality of leads. The first lead 50 of the plurality of leads is a common drain lead. The second lead 52 is a common source lead. The first die 46 is coupled between the source pad 40 and the first clip 42 via a die bonding or attach material 54 that is electrically and thermally conductive. The die bonding material 54 is on the top side (drain side) of the first die 46 and on the bottom side (source side) of the first die 46. The second die 48 is coupled between the first clip 42 and the second clip 44 via die bonding or attach material 56 that is electrically and thermally conductive. The die bonding material 56 is on the top side (source side) of the second die 48 and on the bottom side (drain side) of the second die 48. The first die 46 of the package 38 includes a gate, a drain, and a source. The second die 48 of the package 38 includes a gate, a drain, and a source, respectively. The gate of the first die 46 and the gate of the second die 48 are connected together or in parallel. The drain of the first die 46 and the drain of the second die 48 are connected together or in parallel and to the first clip 42 and first lead 50. The source of the first die 46 and the source of the second die 48 are connected together or in parallel with the second clip 44 and the second lead 52. As illustrated in FIG. 3, the first die 46 and the second die 48 are surrounded by mold compound 58. The package 38 is surrounded by a mold compound 58 but the first lead 50 and second lead 52 along with the source pad 40 are exposed through the mold compound 58 on the bottom surface 62 of the package 38. The top surface 64 of the second clip 44 is exposed on the top side 60 of the package 38. Since the top surface 64 of the second clip 44 is exposed, a heat sink may be coupled to the exposed top surface 64 of the second clip 44. As a result, the package 38 is a dual side cooled package.

Referring to FIG. 4, a top, perspective view of an implementation source out, parallel die package 66 with a cutout 68 in the corner of a second clip 70 is illustrated. The package 66 of FIG. 4 may have substantially similar electrical routing to the packages 14, 38 of FIG. 2 or FIG. 3. In various implementations, the package 66 of FIG. 4 may be a single side cooled package or a dual side cooled package. As illustrated, the package 66 of FIG. 4 includes a plurality of leads, a first clip 72, a second clip 70, a first die 74, and a second die 76. The second clip 70 further includes a cutout 68 on the corner of the clip 70 that exposes a portion of the second die 76 and a gate pad 78 of the second die 76, which is configured to permit wirebonding to the gate pad 78 of the gate of the second die 76. In various implementations, the cutout 68 may be a variety of shapes (curved, straight edged angled, squared, rounded, etc.) and may be located in a corner of the clip, a side of the clip, or on any other area of the second clip depending on the location of the gate pad 78 on the second die 76. Referring to FIG. 4, a wirebond 80 is illustrated. The wirebond 80 forms an electrical connection between a third lead 82 of the plurality of leads and the gate pad 78 of the second die 76. The gate of the first die 74 is also electrically connected to the third lead 82 of the plurality of leads. As a result, the gate of the first die 74 and the gate of the second die 76 are electrically connected and commonly controlled through the third lead 82. As illustrated, the first clip 72 is coupled to the drain of the first die 74 and coupled to the drain of the second die 76. As a result, the package 66 is a source out package as the source of the second die 76 is coupled to the second clip 70 and the source of the first die 74 is coupled to a source pad (not show in FIG. 4) and the plurality of leads and so facing the outer surfaces of the package 66.

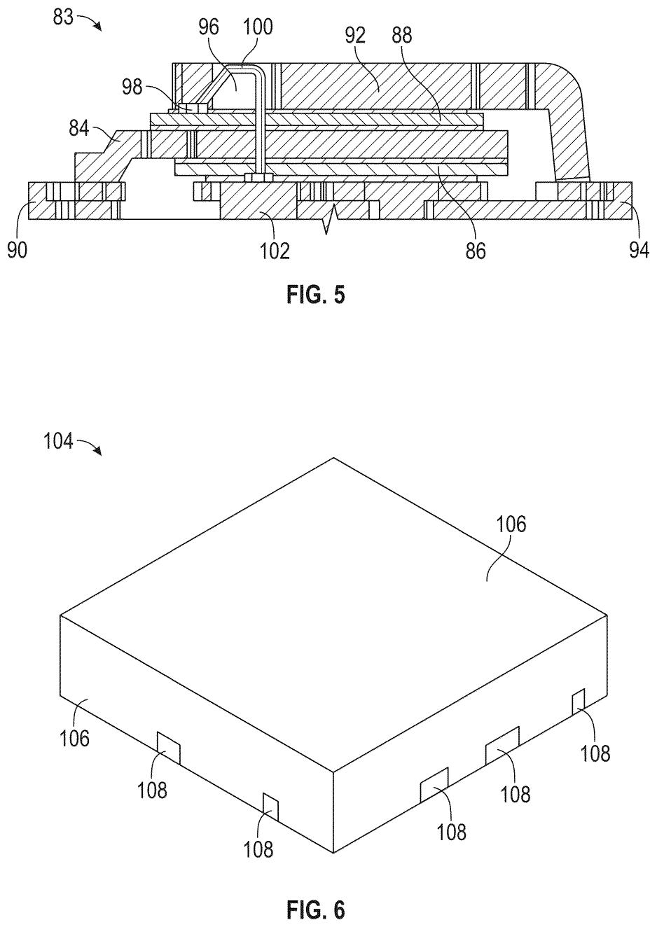

Referring to FIG. 5, a side, cross-sectional view of an implementation of semiconductor package 83 is illustrated. The package 83 may be substantially similar to the package of FIG. 4. Referring to FIG. 5, a plurality of leads are illustrated and are formed from a lead frame. As illustrated in FIG. 5, a first clip 84 is coupled between the drains of a first die 86 and a second die 88. The first clip 84 is coupled to a first lead 90 (common drain lead) of the plurality of leads on the left side of FIG. 5. A second clip 92 is coupled on top of the second die 88 and to a source pad attached to the source of the first die 86. The second clip 92 is coupled to a second lead 94 (common source lead) of the plurality of leads on the right side of FIG. 5. The second clip 92 includes a cutout 96 positioned on the corner of the second clip 92. The cutout 96 exposes the second die 88 and is configured to permit wirebonding to the pad 98 of the gate of the second die 88. Referring to FIG. 5, a wirebond 100 is illustrated which forms an electrical connection to a third lead 102 (common gate lead) of the plurality of leads and to the gate of the second die 88. The gate of the first die 86 is also electrically connected to the third lead 102 of the plurality of leads. As a result, the gate of the first die 86 and the gate of the second die 88 are electrically connected and commonly controlled through the third lead 102.

Referring to FIG. 6, a top perspective view of a single side cooled implementation of the package of FIG. 4 is illustrated. FIG. 6 illustrates a package 104 after completion of an overmolding process. As illustrated, the package 104 is surrounded by mold compound 106 on the top and sides of the package 104. A plurality of leads 108 are exposed on the sides of the package 104. The mold compound 106 covers the top surface of the package and the second clip. As a result, the package 104 illustrated in FIG. 6 is cooled from the lead side of the package.

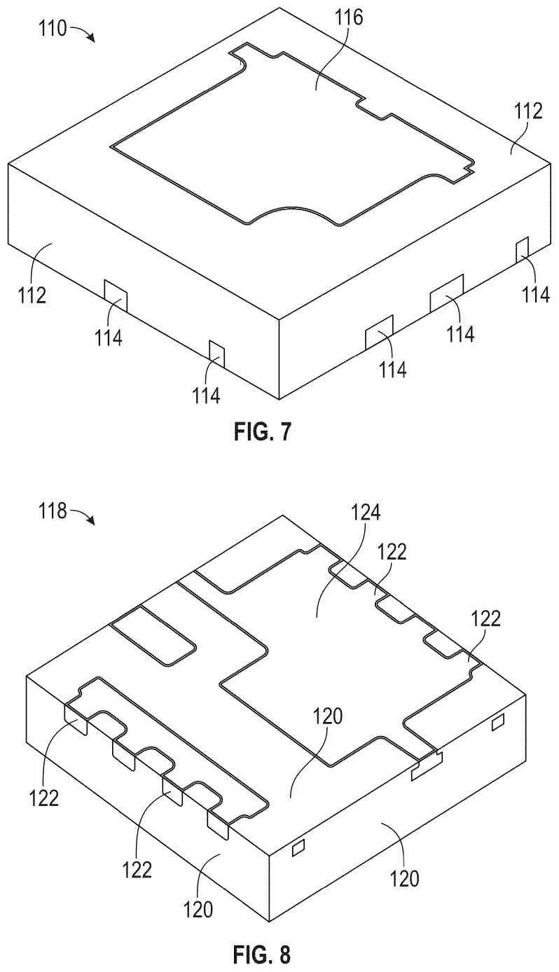

Referring to FIG. 7, a top perspective view of a dual side cooled implementation of the package of FIG. 4 is illustrated. FIG. 7 illustrates a package 110 after completion of an overmolding process. As illustrated, the package 110 is surrounded by mold compound 112 on the top and sides of the package 110. A plurality of leads 114 (including gate, source, and drain leads) are exposed on the sides of the package 110. The mold compound 112 does not fully cover the top surface of the package. As a result, a second clip 116 of the package 110 is exposed and the package 110 illustrated in FIG. 7 is a dual side cooled package allowing for heat flow out both surface of the package 110.

Referring to FIG. 8, a bottom perspective view of the package implementation of FIG. 7 including the mold compound is illustrated. A similar structure could also be present in the package implementation of FIG. 6, as the bottom lead and pad design can be common between single and dual side cooled packages. The package 118 of FIG. 8 may be a single side cooled package or a dual side cooled package. As illustrated, the package 118 is surrounded by mold compound 120 on the sides and the bottom of the package 118. Leads 122 (gate, source, and drain) are exposed on the sides of the package 118 and on the bottom of the package 118. A source pad 124 is also exposed on the bottom side of the package 118.

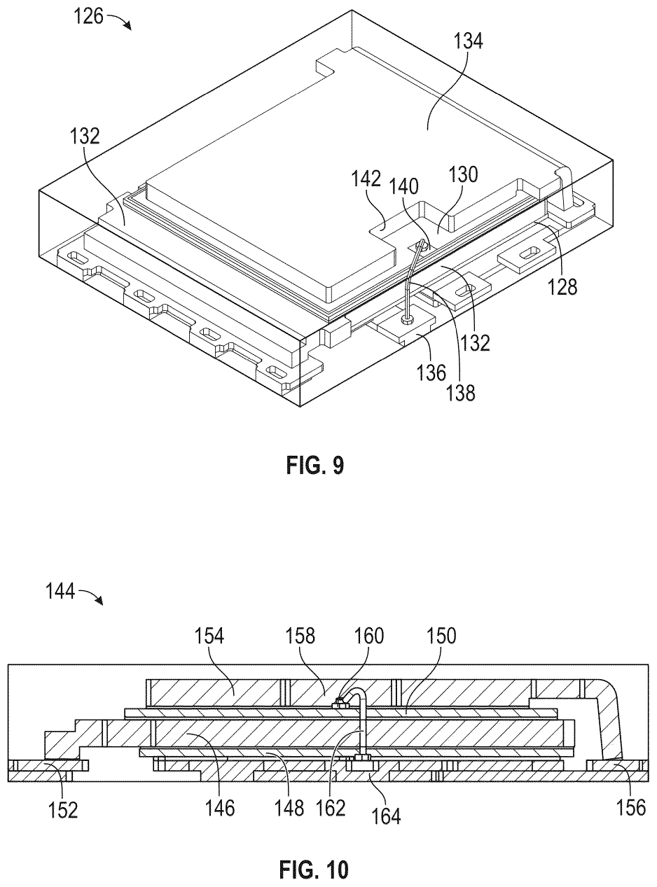

Referring to FIG. 9, a top perspective view of an implementation of a source out, parallel die package with a cutout in a side of an implementation of second clip is illustrated. As illustrated, the package 126 includes a plurality of leads, a first die 128, a second die 130, a first clip 132, and a second clip 134. A third lead 136 of the plurality of leads is illustrated which acts as a common gate lead. The third lead 136 is coupled to a wirebond 138 which, in turn, is wirebonded to a gate pad 140 of the second die 130. The second clip 134 includes a cutout 142 in the middle of a side of the second clip 134 that exposes the gate pad 140 of the second die 130. As illustrated, the second clip 134 covers the majority of the top surface of the second die 130 but exposes the gate pad 140 on top of the second die 130 through the cutout 142 to facilitate wirebonding the third lead 136 to the gate pad 140 of the second die 130.

Referring to FIG. 10, a side, cross-sectional view of a package 144 is illustrated. The package 144 may be substantially similar to the package of FIG. 9. Referring to FIG. 10, a plurality of leads are illustrated. The plurality of leads of the package 144 are formed from a lead frame. As illustrated in FIG. 10, a first clip 146 is coupled between a first die 148 and a second die 150 and electrically connects the drains of the two die to the clip. The first clip 146 is coupled to a first lead 152 (common drain lead) of the plurality of leads on the left side of FIG. 10. A second clip 154 is coupled on top of the second die 150 to a source of the second die 150 and to a source pad attached to the source of the first die 148. The second clip 154 is coupled to a second lead 156 (common source lead) of the plurality of leads frames on the right side of FIG. 10. The second clip 154 includes a cutout 158 positioned on the side of the second clip 154. The cutout 158 exposes the gate pad 160 of the second die 150 and is configured to permit wirebonding to the gate pad 160 of the gate of the second die 150. Referring to FIG. 10, a wirebond 162 is illustrated which forms an electrical connection to a third lead 164 (common gate lead) of the plurality of leads and to the gate 160 of the second die 150. The gate 160 of the first die 150 is also electrically connected to the third lead 164 of the plurality of leads. As a result, the gate of the first die 148 and the gate of the second die 150 are electrically connected together and commonly controlled through the third lead 164.

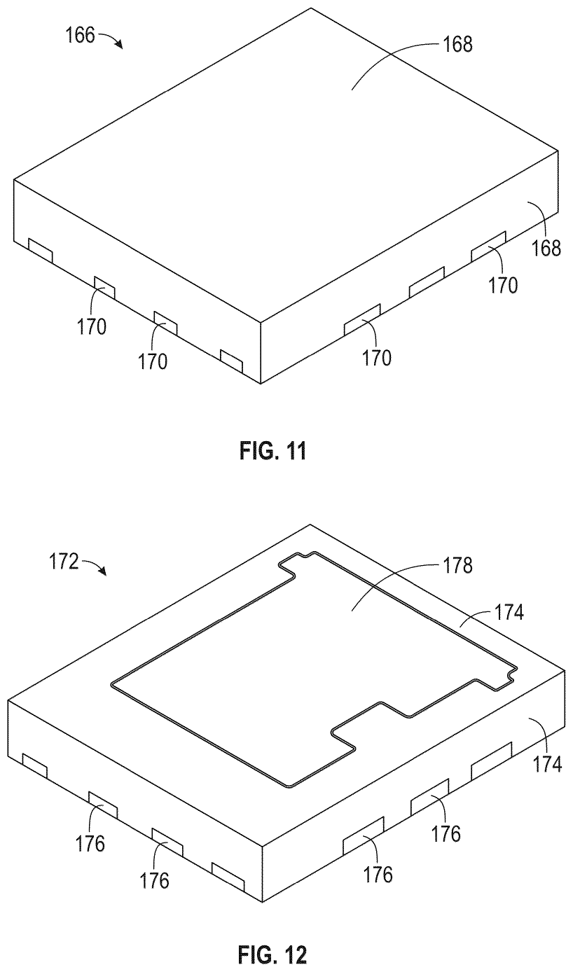

Referring to FIG. 11, a top perspective view of a single side cooled implementation of a package 166 is illustrated. The package 166 of FIG. 11 may be substantially similar to the package of FIG. 9. FIG. 11 illustrates the package 166 after completion of an overmolding process. As illustrated, the package 166 is surrounded by mold compound 168 on the top and sides of the package 166. A plurality of leads 170 are exposed on the sides of the package 166. The mold compound 168 covers the top surface of the package 166 and the second clip. As a result, the package 166 illustrated in FIG. 11 is a single side cooled package as heat transfer is carried out through the lead side of the package.

Referring to FIG. 12, a top perspective view of a dual side cooled implementation of a package 172 is illustrated. The package 172 of FIG. 12 may have internal structure substantially similar to the package of FIG. 9. FIG. 12 illustrates a package 172 after completion of an overmolding process. As illustrated, the package 172 is surrounded by mold compound 174 on the top and sides of the package 172. A plurality of leads 176 are exposed on the sides of the package 172. The mold compound 174 does not fully cover the top surface of the package 172. As a result, a second clip 178 of the package 172 is exposed and the package 172 illustrated in FIG. 12 is a dual side cooled package where heat transfer can take place through the second clip 178.

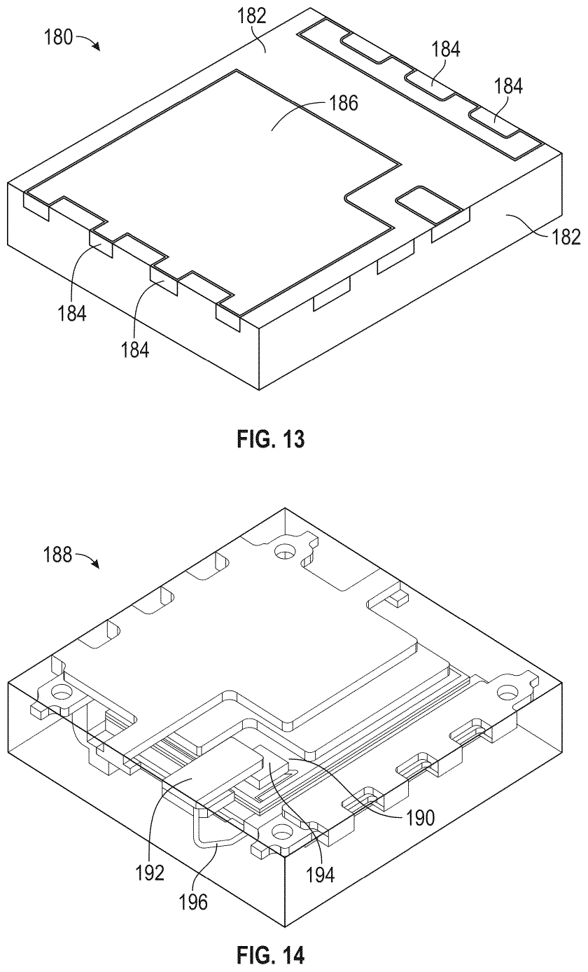

Referring to FIG. 13, a bottom perspective view of an implementation of a package 180 including a mold compound is illustrated. The internal structure of the package 180 of FIG. 13 may be substantially similar to the package of FIG. 11 or FIG. 12. The package 180 of FIG. 13 may be a single side cooled package or a dual side cooled package. As illustrated, the package 180 is surrounded by mold compound 182 on the sides and the bottom of the package 180. Leads 184 (drain, source, and gate) are exposed on the sides of the package 180 and on the bottom of the package 180. A source pad 186 is exposed on the bottom side of the package 180.

Referring to FIG. 14, a bottom see-through perspective view of an implementation of a semiconductor package 188 with a common gate lead is illustrated. The bottom surface of a first die 190 is illustrated in FIG. 14. The gate connection of the first die 190 is coupled to a gate lead 192 of the package 188 through a half etched standoff 194. A wirebond 196 is illustrated coupled to the top surface of the gate lead 192. The wirebond 196 is also coupled to a gate pad of a second die on the top surface of the second die (not show in this figure). As a result, the gate of the first die 190 and the gate of the second die are electrically connected and commonly controlled through the gate lead 192.

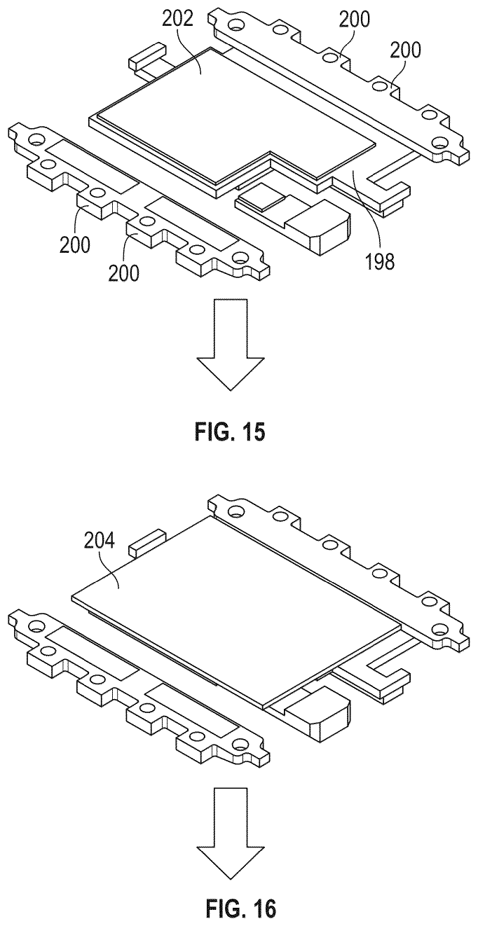

Referring to FIGS. 15-22, a semiconductor package is illustrated after various assembly processes have been completed to form a package like that illustrated in FIG. 7. FIG. 15 illustrates a semiconductor package including components of a leadframe that include source pad 198 and a plurality of leads 200. Further, FIG. 15 illustrates a die attach material 202 after the die attach material 202 has been applied to the top of the source pad 198 in preparation for receiving a semiconductor die thereon.

FIG. 16 illustrates the semiconductor package of FIG. 15 after bonding of a first die 204 on top of the source pad 198 using the die attach material 202. The first die 204 is coupled in a source down configuration to place the source of the die in electrical connection with the source pad and a source lead of the plurality of leads 200.

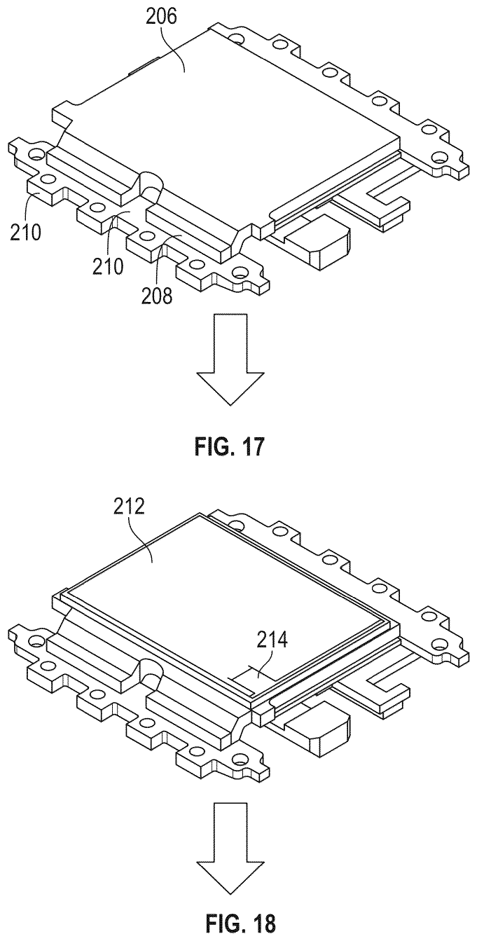

FIG. 17 illustrates the semiconductor package of FIG. 16 after a first clip 206 has been bonded to a top of the first die 204 using a die bonding material which may the same die bonding material as used previously or a different one. As illustrated, the base 208 of the first clip 206 is coupled to a first lead 210 (common drain lead) of the plurality of leads 200.

FIG. 18 illustrates the semiconductor package of FIG. 17 after a second die 212 has been coupled on top of the first clip 206 after the second die 212 using a die bonding material. The second die 212 is coupled in a source up configuration with its drain side coupled to the first clip 206 and to the first lead 210 so that the package is in a source out package configuration. A gate pad 214 of the second die 212 is illustrated on the top corner of the second die 212.

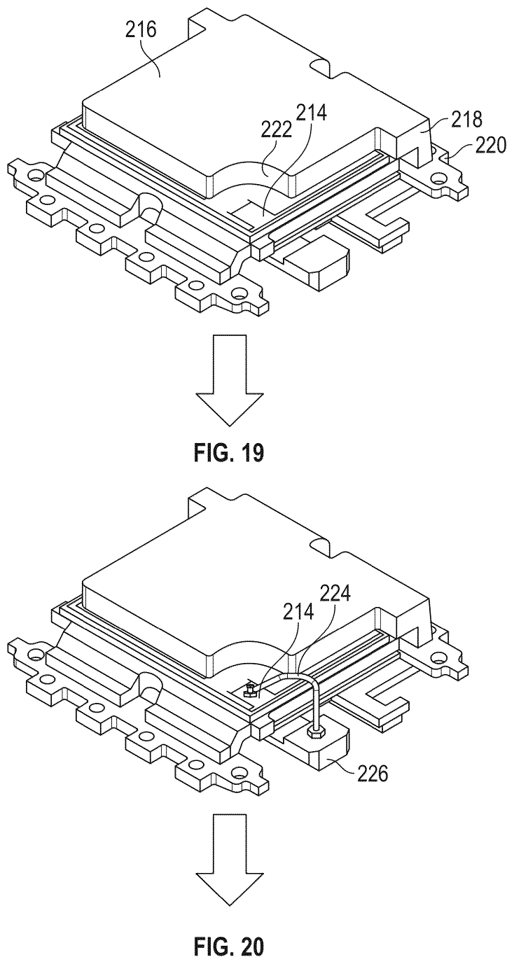

FIG. 19 illustrates the semiconductor package of FIG. 18 after a second clip 216 has been coupled on top of the second die 212 using a die bonding material. The base 218 of the second clip is coupled to a second lead 220 (common source lead) of the plurality of leads 200 which allows the sources of the first die 204 and second die 212 to be electrically connected in common/parallel. The second clip 216 includes a cutout 222 in the corner of the second clip 216 that is exposes the gate pad 214 of the second die 212.

FIG. 20 illustrates the semiconductor package of FIG. 19 after a wirebond 224 has been wirebonded to the gate pad 214 of the second die 212 and to a third lead 226 (common gate lead) of the plurality of leads 200. The wirebond 224 is electrically connected to the gate pad 214 of the second die 212 and to the third lead 226. As a result, the third lead 226 is configured to commonly control the gate of the first die 204 and the gate of the second die 212.

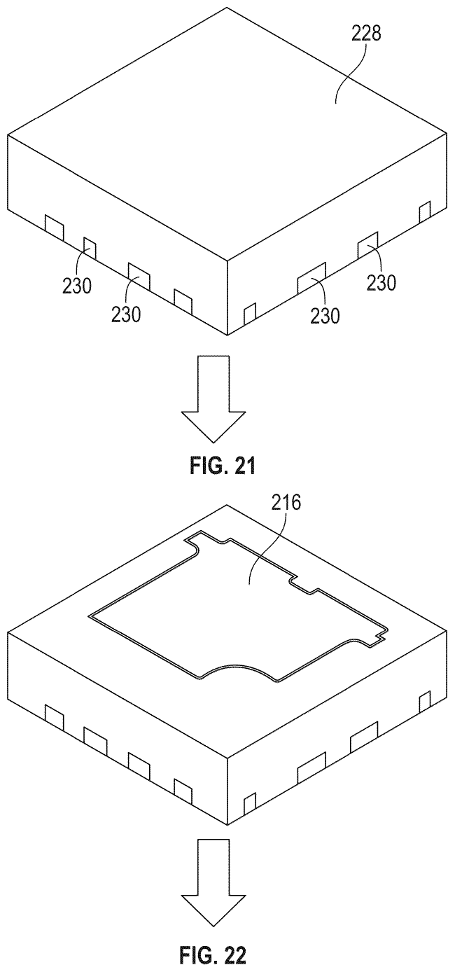

FIG. 21 illustrates the semiconductor package of FIG. 21 after a mold compound 228 has been applied over the package. If the package continued processing in this form, it would resulting in a single sided cooled structure. FIG. 21 illustrates the package a post mold bake process has also been carried out. As illustrated, a plurality of leads 230 (drain, source, and gate) are now exposed on the sides of the package.

FIG. 22 illustrates the semiconductor package of FIG. 21 package after a package grind has been completed on the top layer. As a result, the second clip 216 is exposed on the top of the package and the package is now a dual side cooled structure. The package may be chemically dipped for cleaning after grinding in various method implementations. Further, the package may be plated in, by non-limiting example, tin, nickel, silver, tin/silver, or any other desired solderable material. In various implementations, strip marking, strip mounting, laser marking, and package saw singulation may then be carried out in various method implementations to form a completely assembled dual side cooled package. If a single side cooled package was desired, the packing grinding and chemical dipping processes would be omitted.

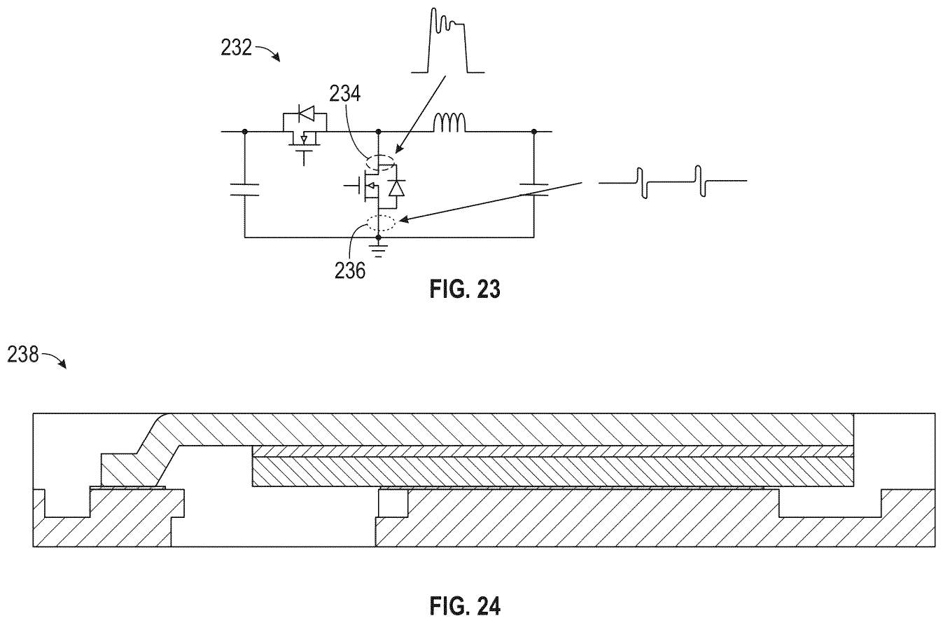

Referring to FIG. 23, an electrical schematic 232 of a circuit forming a synchronous buck that includes single die device packages is illustrated. Referring to FIG. 23, a drain terminal 234 and source terminal 236 are illustrated. The single die devices have been observed to cause high electromagnetic interference (EMI) effects when the circuit is coupled with an inductor or other circuit component that has a high inductance. As illustrated in FIG. 23, the drain terminal 234 has higher voltage and current transient. Further, the source terminal 236 connects to a ground with very a small voltage and current transient. The EMI of the illustrated existing device in FIG. 23 when coupled with a inductor may create, by non-limiting example, an antenna effect that is disruptive to other devices in the area.

Referring to FIG. 24, a side cross-sectional view of a single die device package 238 is illustrated. The package illustrated in FIG. 24 may exhibit the electrical behavior illustrated in FIG. 23 in part because two single die packages are needed in the synchronous buck which have separate gate, drain, and source lead connections which aid in setting up an antenna effect with the transformer. Also, because the drain is exposed, the high di/dt and transient di/dt behavior of the drain terminal increases the antenna effect and reduces EMI performance.

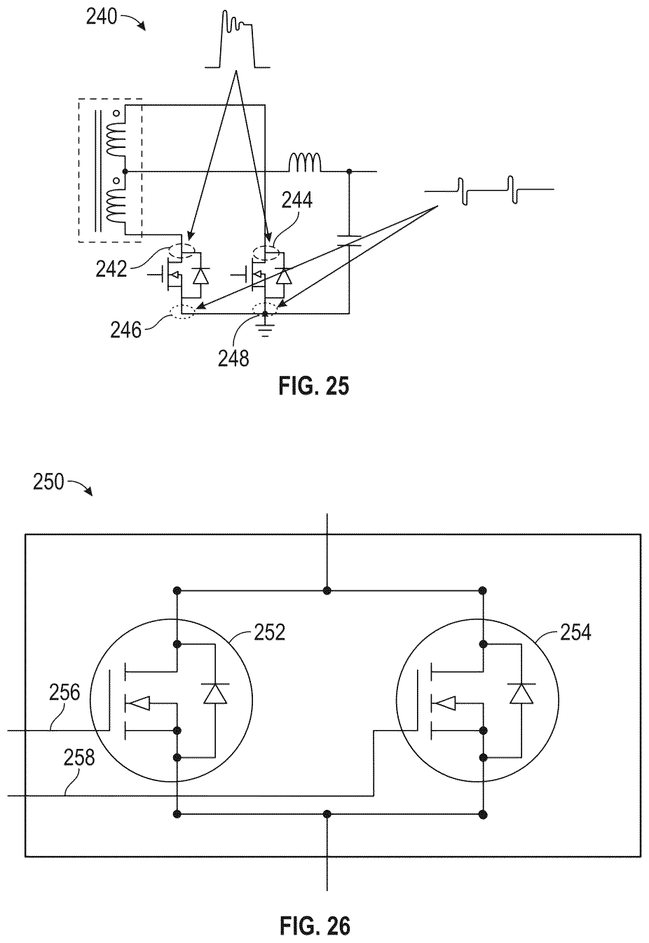

Referring to FIG. 25, an implementation of an electrical circuit 240 that includes a source terminal for center tap transformers that employs a two-die paralleled device package like those disclosed herein that have a common gate lead is illustrated. Referring to FIG. 25, a first drain terminal 242, a second drain terminal 244, a first source terminal 246, and a second source terminal 248 are illustrated. As illustrated in FIG. 25, the drain terminals 242, 244 have a higher voltage and current transient. Further, the source terminals 246, 248 connect to a ground with a very small voltage and current transient. The resulting package may exhibit increased power output compared to existing devices and the ON-resistance may be reduced by at least 40% compared to electrical circuits that employ single die packages. Furthermore, the efficiency of the electrical circuit 240 illustrated in FIG. 25 may be increased through reduced conduction loss compared to circuits that employ single die packages at the same power output rating. In addition, the electrical schematic 240 illustrated in FIG. 25 may result in improved power converter efficiency in wide loading range by using dual gate control. Finally, in this design, the antenna effect EMI with the transformer is substantially reduced. The exposure of the source pad instead of the drain pad in this implementation avoids external exposure of the high di/dt and transient di/dt behavior of the drain terminal. This results in a corresponding reduction in the antenna effect and better EMI performance, particularly when the package is connected to an inductor or circuit component with high inductance.

While the semiconductor package implementations disclosed in this document so far have utilized parallel/common gate connections for both semiconductor die, in other implementations, each gate may be separately controlled. Referring to FIG. 26, an electrical schematic 250 of an implementation of a two die device package with a two gate leads 256, 258 is illustrated. FIG. 26 illustrates another implementation of a two die device where the drains and sources of each die are electrically connected in parallel, but the gates are not commonly connected and so can be separately controlled by a gate driver or other system. Referring to FIG. 26, a first die 252, a second die 254, a first gate lead 256, and a second gate lead 258 are illustrated.

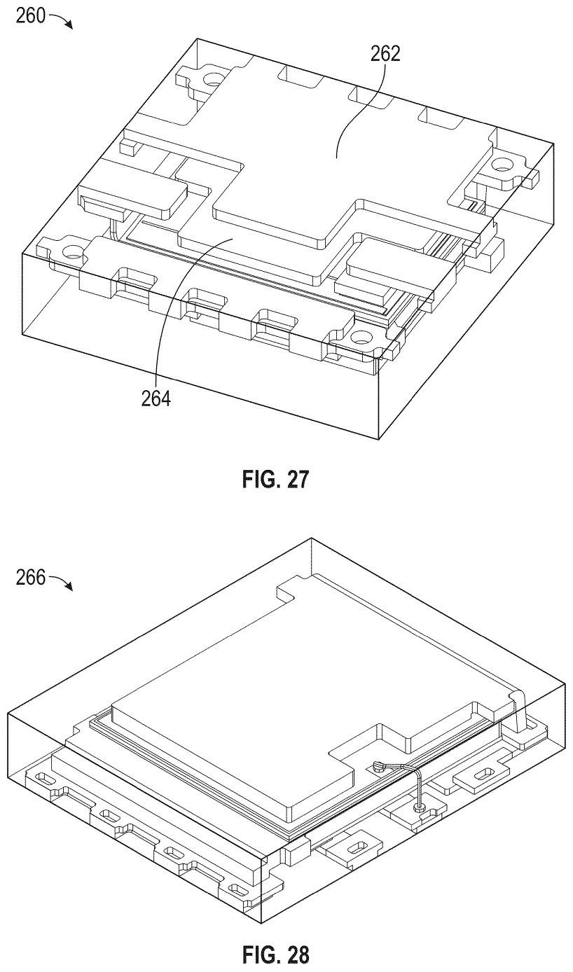

Referring to FIG. 27, a bottom perspective see-through view of an implementation of a two die source out semiconductor device package 260 with a two gate leads is illustrated. In this implementation, a gate lead is present on the right and left sides of the package where one gate lead is connected to a first die oriented source side down and coupled to a source pad and the other gate lead is wirebonded to a second die oriented source side up and coupled to a second clip that forms a common source connection. This package 260 may provide various performance improvements. In this implementation, the source pad 262 may be cut in various different shapes that expose a first clip 264 from the bottom view.

Referring to FIG. 28, a top perspective view of an implementation of a two die source out semiconductor device package 266 with two gate leads is illustrated. The implementation of a dual gate device illustrated in FIG. 28 may provide the same performance improvements as the device illustrated in FIG. 27. As illustrated here, this package design may also utilize a cutout to allow for wirebonding of the gate pad of the second semiconductor die to its corresponding gate lead.

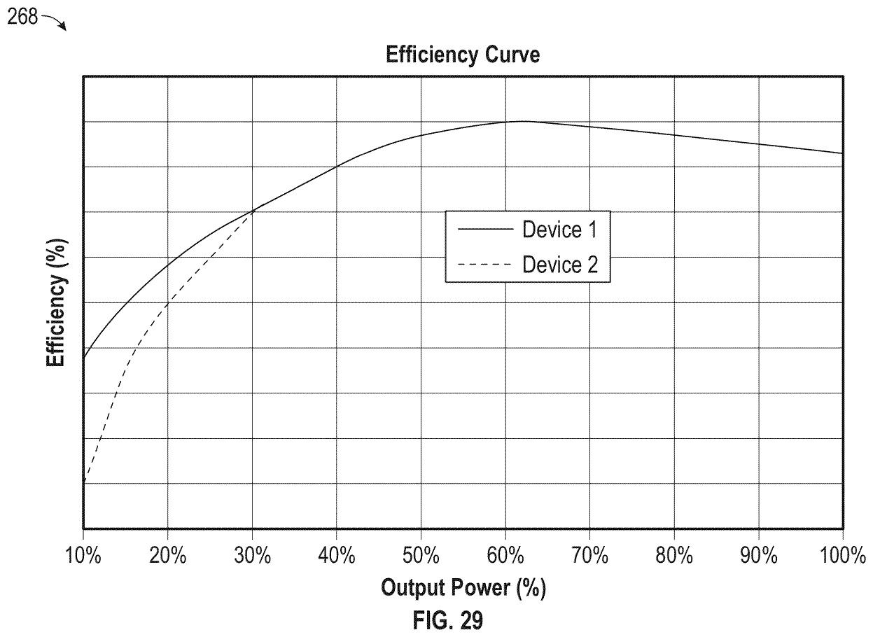

Referring to FIG. 29, a graph 268 showing an efficiency curve for a semiconductor device having individual gate control (Device 1) is illustrated. As illustrated by FIG. 29, individual gate control may reduce MOSFET gate charge loss to improve efficiency under light load conditions. In addition, individual gate control may increase efficiency at lower output power operation conditions.

In places where the description above refers to particular implementations of semiconductor packages and implementing components, sub-components, methods and sub-methods, it should be readily apparent that a number of modifications may be made without departing from the spirit thereof and that these implementations, implementing components, sub-components, methods and sub-methods may be applied to other semiconductor packages.

What is claimed is:

1. A semiconductor package comprising:
a plurality of leads;
a first clip coupled to a first lead of the plurality of leads;
a second clip coupled to a second lead of the plurality of leads;
a first die coupled between a source pad and the first clip; and
a second die coupled between the first clip and the second clip;
wherein the first die comprises a gate, a drain, and a source that are connected in parallel with a gate, a drain, and a source of the second die;
wherein the first clip is coupled to the drain of the first die and to the drain of the second die; and
wherein a wirebond electrically connects the gate of the second die to a third lead of the plurality of leads to which the gate of the first die is also electrically connected.

2. The package of claim 1, wherein the package is a single side cooled package.

3. The package of claim 1, wherein the package is a dual side cooled package.

4. The package of claim 1, wherein the gate of the first die and the gate of the second die are commonly controlled using the third lead.

5. The package of claim 1, wherein the first lead of the plurality of leads is a common drain lead.

6. The package of claim 1, wherein the second clip is configured to expose a gate pad of the second die.

7. The package of claim 1, wherein the first die and the second die are surrounded by a mold compound.

8. A semiconductor package comprising:
a first lead, a second lead, a third lead, and a source pad;
a first clip coupled to the first lead;
a second clip coupled to the second lead;
a first die coupled between the source pad and the first clip; and
a second die coupled between the first clip and the second clip;
wherein the first die has a gate, a drain, and a source that are connected in parallel with a gate, a drain, and a source of the second die;
wherein the first clip is coupled to the drain of the first die and to the drain of the second die;
wherein the gate of the first die and the gate of the second die are coupled to the third lead; and
wherein the second clip further comprises a cutout that exposes a pad of the gate of the second die.

9. The package of claim 8, wherein the package is a single side cooled package.

10. The package of claim 8, wherein the package is a dual side cooled package.

11. The package of claim 8, wherein the third lead is used to commonly control the gate of the first die and the gate of the second die.

12. The package of claim 8, wherein the first lead is a common drain lead.

13. The package of claim 8, wherein the cutout of the second clip is configured to permit wirebonding to the pad of the gate of the second die.

14. A semiconductor package comprising:
a first drain lead coupled to a first clip;
a second source lead coupled to a second clip;
a first die comprising a drain coupled between a source pad and the first clip, the drain of the first die coupled to the first clip; and
a second die comprising a drain coupled between the first clip and the second clip, the drain of the second die coupled to the first clip;
wherein the first die has a first gate and the second die has a second gate;
wherein the first gate and the second gate are electrically connected through a wirebond; and
wherein the package is configured to decrease electromagnetic interference (EMI) in an inductor when coupled with the inductor.

15. The package of claim 14, wherein the electromagnetic interference (EMI) is an antenna effect.

16. The package of claim 14, wherein the package is a single side cooled package.

17. The package of claim 14, wherein the package is a dual side cooled package.

18. The package of claim 14, wherein the package further comprises a common gate lead electrically connected with the first gate and the second gate.

19. The package of claim 14, wherein the first drain lead is a common drain lead.

20. The package of claim 14, wherein the second clip is coupled to a common source lead.
